(19) United States
(12) Patent Application Publication
(10) Pub. No.: US 2006/0278523 A1
(43) Pub. Date: Dec. 14, 2006

(54) Real-time adjustable mechanism of shielding plate in sputtering vacuum chamber design

(75) Inventors: Geeng Jen Sheu, Taichung City (TW); Chung Chung Liu, Taichung County (TW); Jer Rong Chang, Tainan County (TW); Yu Chuan Liu, Tainan County (TW); Tuan Jen Yu, Taichung County (TW); Tai Yuan Huang, Yunlin County (TW)

Correspondence Address: BIRCH STEWART KOLASCH & BIRCH, PO BOX 747, FALLS CHURCH, VA, 22040-0747, US

(73) Assignee: HSIUPING INSTITUTE OF TECHNOLOGY

(21) Appl. No.: 11/147,338

(22) Filed: Jun. 8, 2005

(51) Int. Cl. C23C 14/00

(52) U.S. Cl. 204/298.01

(57) ABSTRACT

A sputtering system includes a chamber with two frames therein. Several shafts are pivoted on the frames for rotation and transport. A shielding plate is placed above the shafts, and several adjustable mechanisms are between the frames and the shielding plate. Each of the adjustable mechanisms has an operation member on an exterior side of the chamber and an inner member in the chamber, which is connected to the operation member and the shielding plate. The inner member has a first section with a threaded hole and a second section with a threaded post screwed into the threaded hole of the first section. As a result, when the operation member is turned, the relative length and position of the inner member is changed to elevate or lower the shielding plate, and hence the gap between the carrier and the shielding plate can be adjusted to the desired allowable value.

### BACKGROUND OF THE INVENTION

1. Field of the Invention

The present invention relates generally to a vacuum deposition system for sputtering process, and more particularly to a real-time and on-line adjustable mechanism of a shielding plate in the sputtering vacuum chamber.

2. Description of the Related Art

FIG. 1 shows a vacuum deposition sputtering system. FIG. 2 shows the flow chart of the sputtering process, which is consisted at least one load chamber, one unload chamber and one sputter (or process) chamber for reactive magnetron sputtering. In the sputter (or process) chamber 10, two support frames 15 are mounted on a bottom of the chamber 10, and several shafts 14 are pivoted on the frames 15 (referring to FIG. 3 and FIG. 4), and several chains 17 are provided to connect the shafts 14 for synchronous motion. A motor 13 is located on an exterior side of the chamber 10 in atmosphere environment and connected to the shaft 14 via a ferrofluidic vacuum rotary feedthrough 33, which is used to deliver the torque and power from atmosphere side into vacuum side. Each of the shafts 14 has two rollers 16 on the both sides. A carrier 12, on which substrates 29 are placed, is rested on the rollers 14 for transport from the front chamber 10 to the next. A cathode 11 is placed on the top of the chamber 10 above the carrier 12, on which a target 28 is provided and mounted.

In the sputtering process, an electric field ionizes an inert gas such as argon. The positive ions 31 with high kinetic energy bombard and attract the surface of the target 28. Sputtering is the removal of atomized material and particles 30 from a target 28 due to energetic bombardment of its surface by ions or neutral particles. It is one method of depositing PVD coatings. The atoms and particles 30 are immersed and then deposited on the surface of substrates 29. However, in practice, the atoms and particles 30 are deposited not only on the substrate 29, but also on the carrier 12, the shafts 14, the frames 15, the rollers 16, the chains 17, and the bottom of the chamber 10, etc.

Because the requirements of vacuum and clean environment, prior to the sputtering procedure a vacuum of less than one ten millionth of an atmosphere must be achieved. If the pollution produced from the chamber 10 and transmission system (e.g. the support frames 15, the shafts 14 and the chains 17, etc.), the particles of impurity will be diffused in vacuum condition and then adhere on the surface of substrates 29. It will cause unusual convexity or exceptional penetrability. It demotes the uniformity of the coating surface, and hence reduces the coating quality, yield factor, and productivity of the sputtering system. Therefore, the quality and the uniformity of the coating surfaces mainly depend on not only the stability of the transmission system, but also the cleanness of the chamber 10.

However, the deposited particles induced by the sputtering process can't be avoided in the internal chamber 10. And the amount will increase with time and influence the cleanness of the chamber 10. As a result, these depositions on the frames 15, the shafts 14 and the chains 17 have to be removed and polished after a predetermined time of use to keep the quality of sputtering. The system usually needs to periodically shut down to maintain and clear the internal surface of the chamber 10 due to the sputtering pollution after a predetermined period. It will reduce the activation of system and the efficiency of production. The chamber 10 has to be re-opened and then assembled in the atmosphere environment. The shafts 14, the frames 15 and chains 17 have to be disassembled for polish and clean. Moreover, the depositions on the surface of teeth of chains 17 may cause jam or fail of transport, and hence result in instability of transmission system.

To prevent the above drawbacks, the sputtering system usually is provided with a shielding plate 18 between the carrier 12 and the frames 15, as shown in FIG. 5. The conventional shielding plate 18, referring to FIG. 6A and FIG. 6B, is provided with bolts 20 screwed into a threaded hole 25 on the frames 15 and springs 19 between the shielding plate 18 and recesses 21 on the frames 15. With the isolation effect of shielding plate 18, the deposited atoms and particles are directly immersed on the shielding plate 18 rather than the frames 15, the shafts 16 and the chains 17. The shielding plate 18 is disposable after a predetermined period and is installed the new one modularly, such that it has no need to shut down to maintain and clear the surfaces of the frames 15, the shafts 16 and the chains 17.

If the gap between the bottom of carrier 12 and the shielding plate 18 is as smaller as possible, the atomized particles will hardly permeate through the space, and the bottom of the carrier 12 will keep clean during the sputtering process. Otherwise, the deposited particles and atoms on the bottom of the carrier 12 will pollute the chamber 10 and also need to be polished periodically. Theoretically, the allowable gap is functional of several factors, such as: the type of inert gas, the target 28, the substrate 29, the level of vacuum condition, the size and shape of the chamber 10, the size and shape of the cathode 11, and the power supply etc. As a result, it is necessary to be adjusted incessantly depending on the sputtering conditions. Generally speaking, it is preferred to be set in a range between 1 mm and 10 mm. Beyond the allowable gap, the atomized atoms and particles will enter the gap and are deposited on the bottom of the carrier 12 that causes pollution when the carrier 12 enters another chamber. Before the sputtering process, it typically has to adjust the gap by screwing the bolts 20 to prevent the atoms and particles diffused the space between the carrier 12 and the shielding plate 18. The only conventional way to know whether the atoms enter the gap between the carrier 12 and the shielding plate 18 is to open the chamber 10 under atmosphere environment and check whether the atoms and particles have deposited on the bottom of the carrier 12. In practice, the check process has to be taken repeatedly in the sputtering process. It will slow down due to the re-outgas process for vacuum requirement and reduce the efficiency of sputtering process. Again, when the operator found the deposition on the bottom of the carrier 12, the pollution had already occurred in the chamber 10 and it will degrade the quality of the coating surfaces.

### SUMMARY OF THE INVENTION

The primary objective of the present invention is to provide a real-time and on-line adjustable mechanism for a sputtering system, in which the gap between the carrier and the shielding plate can be adjusted to the allowable tolerance whenever the deposition on the bottom of carrier is happened.

The secondary objective of the present invention is to provide a sputtering system, which has no need to open the chamber and re-outgas process under atmosphere environment if the gap between the carrier and the shielding plate is needed to be adjusted.

According to the objectives of the present invention, a sputtering system comprises a chamber, frames mounted in the chamber, shafts pivoted on the frames for rotation and transport, a shielding plate placed between the carrier and the shafts, and adjustable mechanisms. Each of the adjustable mechanisms has an operation member on an exterior atmosphere side of the chamber, and an inner member in the inner vacuum side of the chamber, which is connected to the operation member and the shielding plate. The inner member has a first section with a threaded hole and a second section with a threaded post screwed into the threaded hole of the first section. As a result, when the operation member is turned, the relative length and position of the inner member is changed to elevate or lower the shielding plate, and hence the gap is adjustable.

### BRIEF DESCRIPTION OF THE DRAWINGS

FIG. 1 is a sketch diagram of the sputtering process occurred in the sputtering system;

FIG. 2 is a flow chart of the sputtering process;

FIG. 3 is an exploded view of the conventional sputtering system without the shielding plate;

FIG. 4 is a sectional view of the conventional sputtering system without the shielding plate;

FIG. 5 is an exploded view of the conventional sputtering system with the shielding plate;

FIG. 6A is a sectional view of the conventional sputtering system with the shielding plate;

FIG. 6B is an enlarged view of the conventional adjustable mechanism of the shielding plate;

FIG. 7 is an exploded view of a preferred embodiment of the present invention;

FIG. 8A is a sectional view of the preferred embodiment of the present invention, and

FIG. 8B is an enlarged view of the adjustable mechanism of the preferred embodiment of the present invention.

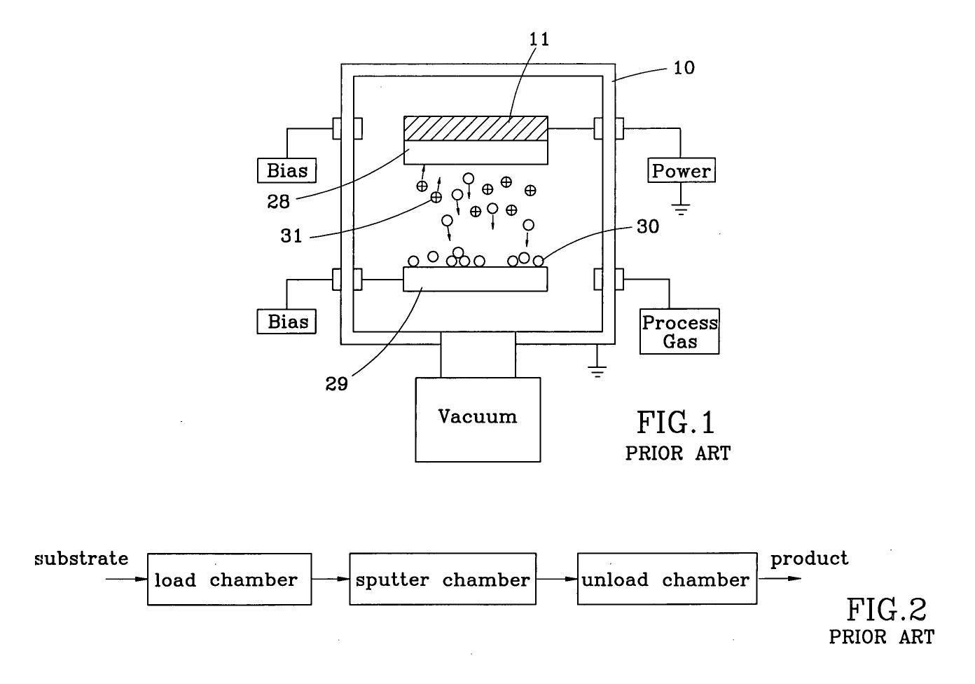

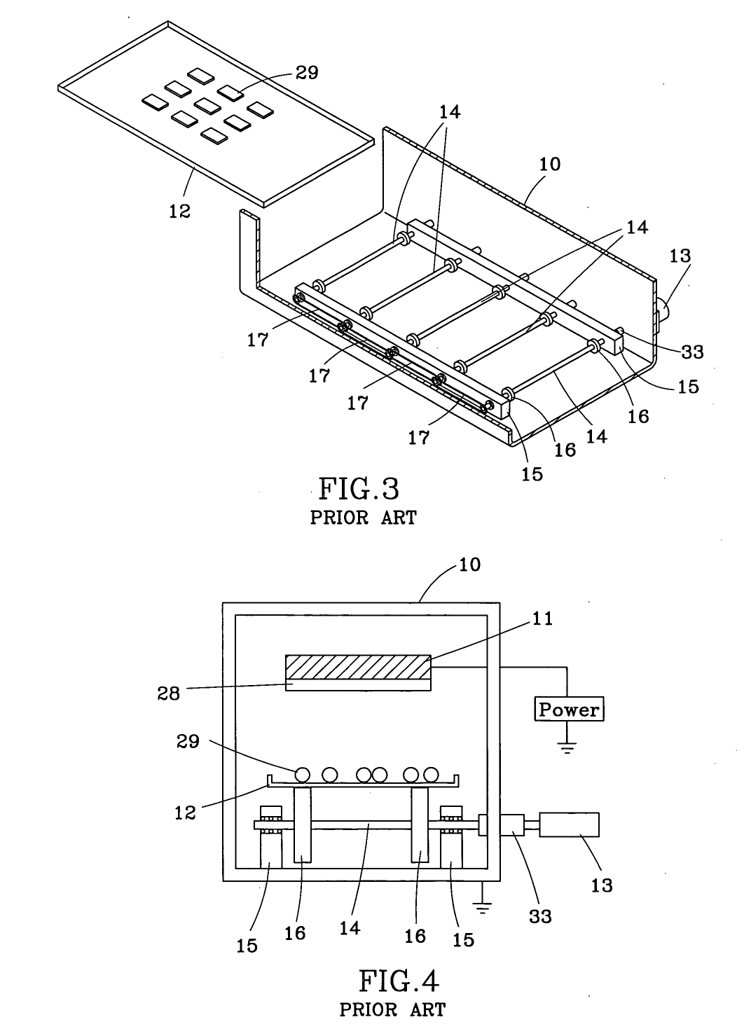

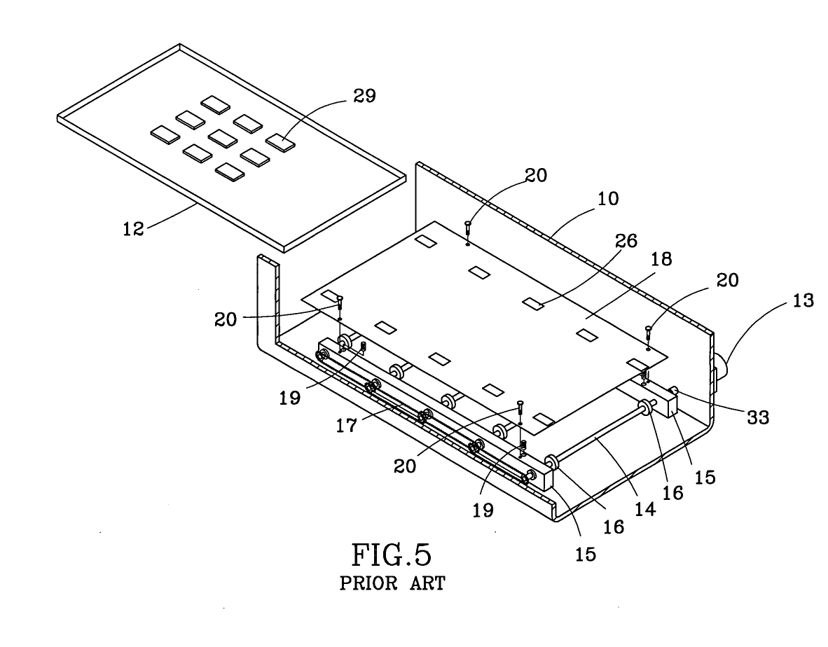

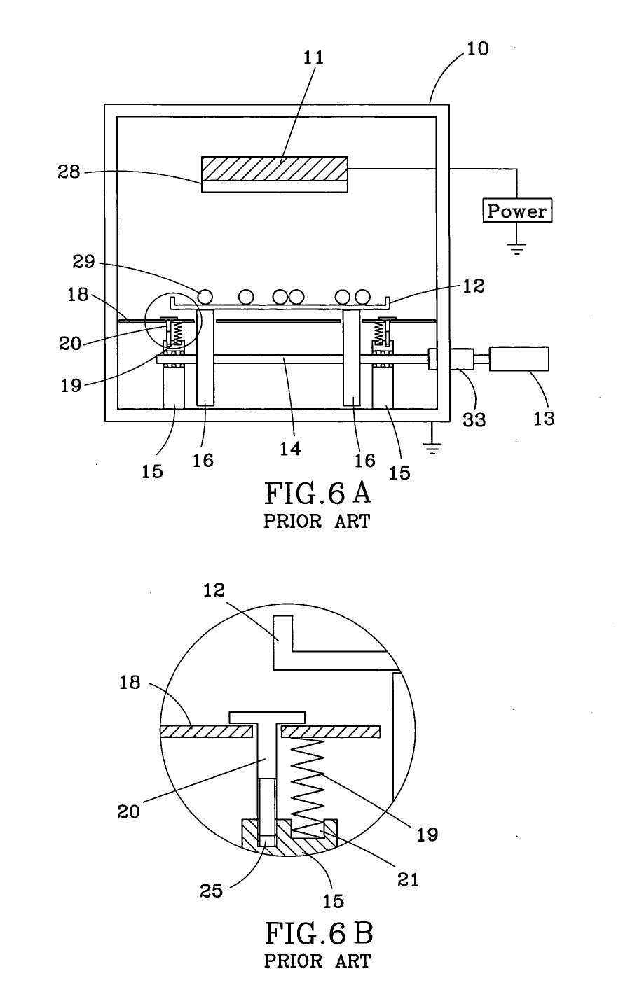

### DETAILED DESCRIPTION OF THE INVENTION

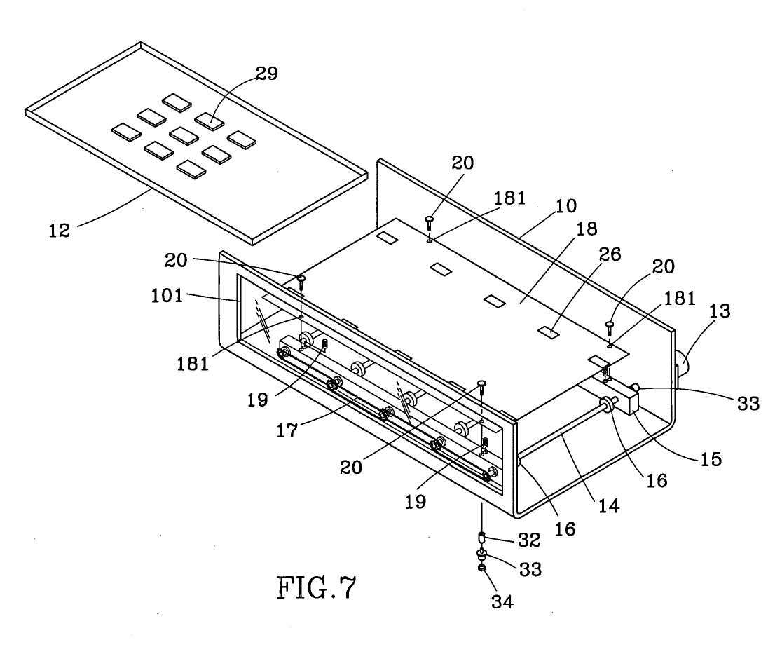

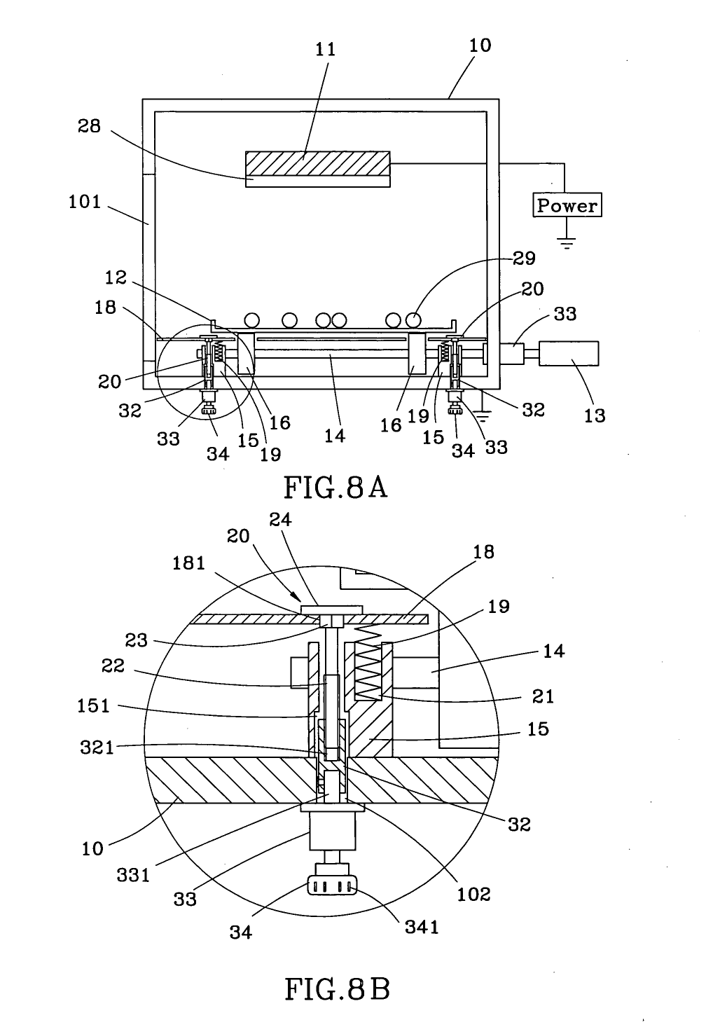

As shown in. FIG. 7 and FIG. 8A, a sputtering system of the preferred embodiment of the present invention comprises a chamber 10 and a window 101 on a sidewall to allow operator to monitor the chamber 10 by visual. In the chamber 10, two frames 15 are provided on a bottom wall, on which five shafts 14 are pivoted. Each of the shafts 14 has two rollers 16 thereon, and several chains 17 are connected to the shafts 14 each other in synchronous motion. A motor 13 is mounted on an exterior side of the chamber 10 and is connected to the shaft 14 via a ferrofluidic vacuum rotary feedthrough 33, which is used to deliver torque and power from atmosphere environment into vacuum environment. A shielding plate 18 is placed on the frames 15 with bores 26 associated with the rollers 16. A carrier 12 is rested on the rollers 16 to transport the substrates 29. A cathode 11 with a target 28 above carrier 12 is provided in the chamber 10.

As shown in FIG. 8B, the present invention further provides four adjustable mechanisms, each of which has an operation member 34, a ferrofluidic vacuum rotary feedthrough 33, an inner member 32 and 20, and a spring 19.

The operation member 34 is knob in the present invention, which is connected to an axle 331 of the ferrofluidic vacuum rotary feedthrough 33. The operation member 34 can be with a scale measure 341 to verify the degrees of rotation and calculate the fine distance.

The ferrofluidic vacuum rotary feedthrough 33 is mounted on an exterior side of the bottom wall of the chamber 10 with the axle 331 extended into the chamber 10 via a bore 102. The bore 102 is under the frame 15 and communicated with a tunnel 151 in the frame 15.

The inner member is received in the tunnel 151 of the frame 15, which has a first section 32 and a second section 20. The first section 32 has an end fixed to the axle 331 of the ferrofluidic vacuum rotary feedthrough 33 and an opposite end with a threaded hole 321. The second section 20 is a bolt with a head portion 24 and a threaded post 22. There is a hexagonal portion 23 between the head portion 24 and the threaded post 22. The shielding plate 18 is provided with hexagonal holes 181, and the threaded posts 22 of the second sections 20 are inserted into the hexagonal holes 181 of the shielding plate 18 from a top and then screwed into the threaded holes 321 of the first sections 32. Because the hexagonal portion 23 of the bolt is mated and matched with the hexagonal holes 181 of the shielding plate 18, the second sections 20 will be restricted from rotation and be in synchronous motion with the shielding plate 18 due to the constrained hexagonal shape.

The frames 15 have at least four recesses 21 at the corners of the chamber 10, in which the springs 19 are received and placed to urge the shielding plate 18.

When an operator turns the operation members 34 according to the scale measure 341, the first sections 32 of the inner members are turned relative to the second sections 20, such that the relative length and position of the second sections 20 is changed. As a result, the shield plate 18 is elevated or lowered, and hence the gap between the carrier 12 and the shielding plate 18 can be adjusted to the desired allowable value.

In the sputtering process, the operator can monitor the carrier 12 and the shielding plate 18 via the window 101. When the operator finds the atoms and particles entering a gap between the carrier 12 and the shielding plate 18, and deposited on the bottom of the carrier 12, he/she can turn the operation members 34 immediately to elevate or lower the shield plate 18 for adjustment of a allowable gap between the carrier 12 and the shielding plate 18 under the atmosphere environment. The conventional process of re-open and assemble of the chamber 18 is unnecessary. By the way, the shielding plate 18 of the adjustable mechanism is also designed to be disposable after a predetermined period and can be installed the new one modularly, such that it has no need to shut down to maintain and clear regularly.

What is claimed is:

1. A sputtering system, comprising a chamber, frames mounted in the chamber, shafts pivoted on the frames for rotation and transport, a shielding plate above the shafts, and adjustable mechanisms, wherein each of the adjustable mechanisms has an operation member on an exterior side of the chamber and an inner member in the chamber, which is connected to the operation member and the shielding plate respectively, wherein the inner member has a first section with a threaded hole and a second section with a threaded post screwed into the threaded hole of the first section, such that when the operation member is turned, a length of the inner member is changed to elevate or lower the shielding plate.

2. The sputtering system as defined in claim 1, wherein the chamber has a window.

3. The sputtering system as defined in claim 1, wherein each of the adjustable mechanisms further has a ferrofluidic vacuum rotary feedthrough with an axle connected to the operation member and the inner member, respectively.

4. The sputtering system as defined in claim 1, wherein each of the adjustable mechanisms further has springs with opposite ends urging the frames and the shielding plate, respectively.

5. The sputtering system as defined in claim 4, wherein the frames have recesses, in which the springs are received and placed respectively.

6. The sputtering system as defined in claim 1, wherein the frames have tunnels, in which the inner members are received respectively.

7. The sputtering system as defined in claim 1, wherein the shielding plate has polygonal holes, and each of the second sections of the inner members of the adjustable mechanisms has a polygonal portion mated and matched with the polygonal holes respectively.

8. The sputtering system as defined in claim 1, wherein the operation member has a scale measure.
